(19) United States
(12) Patent Application Publication
(10) Pub. No.: US 2026/0238231 A1
(43) Pub. Date: Aug. 13, 2026

(54) CONCATETATION OF CHANNEL CODES IN FINITE BLOCK LENGTH REGIMES

(71) Applicant: Lenovo (United States) Inc., Morrisville, NC (US)

(72) Inventors: Abir BEN HADJ FREDJ, Frankfurt am Main (DE); Razvan-Andrei STOICA, Essen (DE)

(21) Appl. No.: 19/048,464

(22) Filed: Feb. 7, 2025

(51) Int. Cl. H03M 13/11; H04L 1/00

(52) U.S. Cl. CPC H03M 13/116; H04L 1/0057; H04L 1/0071

(57) ABSTRACT

Various aspects of the present disclosure relate to the concatenation of channel codes in finite block length regimes. For example, an encoder may concatenate different quasi-cyclic LDPC codes, or QC-LDPC codes, where an inner code has a fixed high-rate code and an outer code is rate adaptable and/or flexible. A convolutional or block interleaver may be implemented between the concatenated codes, which may add a higher minimum distance and fewer low weight codewords. Thus, concatenated QC-LDPC codes may be useful for finite block lengths, where the codes are uniformly applied across both data channels and control channels of a network (e.g., a 6G network).

### TECHNICAL FIELD

The present disclosure relates to wireless communications, and more specifically to the concatenation of channel codes in finite block length regimes.

### BACKGROUND

A wireless communications system may include one or multiple network communication devices, such as base stations, which may support wireless communications for one or multiple user communication devices, which may be otherwise known as user equipment (UE), or other suitable terminology. The wireless communications system may support wireless communications with one or multiple user communication devices by utilizing resources of the wireless communication system (e.g., time resources (e.g., symbols, slots, subframes, frames, or the like) or frequency resources (e.g., subcarriers, carriers, or the like). Additionally, the wireless communications system may support wireless communications across various radio access technologies including third generation (3G) radio access technology, fourth generation (4G) radio access technology, fifth generation (5G) radio access technology, among other suitable radio access technologies beyond 5G (e.g., sixth generation (6G)).

For example, 6G aims to provide connectivity for services and applications across many vertical domains including factory automation applications, tactile internet services autonomous driving services, extended reality (XR) applications (e.g., virtual reality (VR) and augmented reality (AR) applications), medical applications, and many others. To effectively support these vertical applications, a wireless communications system may implement stringent requirement regarding end-to-end transmission latencies, data throughput, ultra-reliability, packet size flexibility, communications, availability, and so on.

### SUMMARY

An article “a” before an element is unrestricted and understood to refer to “at least one” of those elements or “one or more” of those elements. The terms “a,” “at least one,” “one or more,” and “at least one of one or more” may be interchangeable. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on. Further, as used herein, including in the claims, a “set” may include one or more elements.

The present disclosure relates to methods, apparatuses, and systems that support the concatenation of channel codes, such as quasi-cycle low-density parity-check (QC-LDPC) codes in finite block length regimes.

A network entity for wireless communication is described. The network entity may be configured to, capable of, or operable to perform one or more operations as described herein. For example, the network entity may comprise at least one memory and at least one processor coupled with the at least one memory and configured to cause the network entity to receive a data block and generate a concatenated quasi-cyclic low-density parity-check (QC-LDPC) code for the data block, by performing a first QC-LDPC encoding of the data block at a first code rate to generate an encoded data block, interleaving QC-LDPC codeword elements of the encoded data block to generate an interleaved encoded data block, and performing a second QC-LDPC encoding of the interleaved encoded data block at a second code rate.

A method performed or performable by the network entity is described. The method may comprise receiving a data block and generating a concatenated quasi-cyclic low-density parity-check (QC-LDPC) code for the data block, by performing a first QC-LDPC encoding of the data block at a first code rate to generate an encoded data block, interleaving QC-LDPC codeword elements of the encoded data block to generate an interleaved encoded data block, and performing a second QC-LDPC encoding of the interleaved encoded data block at a second code rate.

In some implementations of the network entity and method described herein, the first code rate is close to 1 and the second code is flexible. In some implementations of the network entity and method described herein, the second code rate is close to 1 and the first code is flexible.

In some implementations of the network entity and method described herein, the network entity and method may further be configured to, capable of, performed, performable, or operable to puncture an output of an encoder that performed the first QC-LDPC encoding to reduce low weight codeword elements within the first QC-LDPC encoding.

In some implementations of the network entity and method described herein, the first QC-LDPC encoding and the second QC-LDPC encoding are concatenated in a serial manner. In some implementations of the network entity and method described herein, the first QC-LDPC encoding and the second QC-LDPC encoding are concatenated in a parallel manner.

In some implementations of the network entity and method described herein, the network entity and method may further be configured to, capable of, performed, performable, or operable to interleave QC-LDPC codeword elements of the first QC-LDPC encoding using a block interleaver, a convolutional interleaver, or a fitted interleaver. In some implementations of the network entity and method described herein, the network entity and method may further be configured to, capable of, performed, performable, or operable to transmit the concatenated QC-LDPC code to a receiving entity.

A UE for wireless communication is described. The UE may be configured to, capable of, or operable to perform one or more operations as described herein. For example, the UE may comprise at least one memory and at least one processor coupled with the at least one memory and configured to cause the UE to receive a concatenated QC-LDPC code, decode an outer code of the concatenated QC-LDPC code via a first iterative decoder to generate decoded bits, de-interleave decoded QC-LDPC bit elements of the outer code to generate de-interleaved decoded bits, and decode an inner code of the de-interleaved decoded bits via a second iterative decoder.

A processor for wireless communication is described. The processor may be configured to, capable of, or operable to perform one or more operations as described herein. For example, the UE may comprise at least one controller and at least one memory coupled with the at least one controller and configured to cause the processor to receive a concatenated QC-LDPC code, decode an outer code of the concatenated QC-LDPC code via a first iterative decoder to generate decoded bits, de-interleave decoded QC-LDPC bit elements of the outer code to generate de-interleaved decoded bits, and decode an inner code of the de-interleaved decoded bits via a second iterative decoder.

A method performed or performable by the UE is described. The method may comprise receiving a concatenated QC-LDPC code, decoding an outer code of the concatenated QC-LDPC code via a first iterative decoder to generate decoded bits, de-interleaving decoded QC-LDPC bit elements of the outer code to generate de-interleaved decoded bits, and decoding an inner code of the de-interleaved decoded bits via a second iterative decoder.

In some implementations of the UE, processor, and method described herein, the UE, processor, and method may further be configured to, capable of, performed, performable, or operable to de-interleave soft outputs of the first iterative decoder, input the de-interleaved soft outputs to the second iterative decode, interleave soft outputs of the second iterative decoder; and input the interleaved soft outputs of the second iterative decoder to the first iterative decoder.

In some implementations of the UE, processor, and method described herein, the first iterative decoder or the second iterative decoder is a belief propagation decoder. In some implementations of the UE, processor, and method described herein, the first iterative decoder or the second iterative decoder is a min-sum algorithm decoder. In some implementations of the UE, processor, and method described herein, the first iterative decoder or the second iterative decoder is a decoder that applies a message passing algorithm.

In some implementations of the UE, processor, and method described herein, the UE, processor, and method may further be configured to, capable of, performed, performable, or operable to decode the inner code and the outer code of the concatenated QC-LDPC code via a joint iterative decoder, wherein the joint iterative decoder exchanges extrinsic information over a Tanner graph associated with a parity check matrix of the concatenated codes and wherein the concatenated QC-LDPC code is in systematic form.

In some implementations of the UE, processor, and method described herein, the Tanner graph associated with the parity check matrix of the concatenated QC-LDPC code includes a first set of variable nodes representing information bits, a second set of variable nodes representing parity bits of a first encoder, a third set of variable nodes representing parity bits of a second encoder, and a fourth set of variable nodes representing a check on checks.

In some implementations of the UE, processor, and method described herein, the set of variable nodes representing the check on checks is punctured.

### BRIEF DESCRIPTION OF THE DRAWINGS

FIG. 1 illustrates an example of a wireless communications system in accordance with aspects of the present disclosure.

FIG. 2 illustrates an example of signaling a channel code between an NE and a UE in accordance with aspects of the present disclosure.

FIG. 3 illustrates an example serial concatenation of interleaved channel codes in accordance with aspects of the present disclosure.

FIG. 4 illustrates an example Tanner Graph for serially concatenated channel codes in accordance with aspects of the present disclosure.

FIG. 5 illustrates an example parallel concatenation of interleaved channel codes in accordance with aspects of the present disclosure.

FIGS. 6A-6B illustrate example decoder structures in accordance with aspects of the present disclosure.

FIGS. 7A-7B illustrate example graphs depicting the performance of concatenated QC-LDPC codes in accordance with aspects of the present disclosure.

FIG. 8 illustrates an example of a UE in accordance with aspects of the present disclosure.

FIG. 9 illustrates an example of a processor in accordance with aspects of the present disclosure.

FIG. 10 illustrates an example of a network equipment (NE) in accordance with aspects of the present disclosure.

FIG. 11 illustrates a flowchart of a method performed by a UE or an NE in accordance with aspects of the present disclosure.

FIG. 12 illustrates a flowchart of a method performed by a UE or an NE in accordance with aspects of the present disclosure.

### DETAILED DESCRIPTION

A wireless communications system relies on channel codes when performing error detection and correction for data transmitted over a network. For example, a network supporting the 5G radio access technology employs low density parity check (LDPC) codes for transmissions over data channels and cyclic redundancy check (CRC)-aided polar codes for signaling over control channels.

At large block lengths, the performance of LDPC codes can be estimated using asymptotic techniques (e.g., density evolution). However, at finite code lengths, LDPC codes have a limited usefulness due to a lack of understanding of the dynamics of iterative decoding algorithm, leading to the use of the polar codes for control channels.

While the use of two different codes has been effective for 5G networks, 6G networks (or certain services/applications that may be supported in 6G) may benefit from a unified channel coding framework. However, the channel code should exhibit a low block error rate (BLER) and low error floor for both large and finite block lengths balanced by a flexible implementation to facilitate different key performance indicators (KPIs) for the supported applications and services.

For example, a unified channel coding framework can avoid certain issues of implementation, such as drawbacks associated with additional hardware implementations, large power consumption, chip layouts, backward/forward capabilities for standards, and other drawbacks. Thus, a wireless communications system may benefit greatly from employing one of the 5G channel codes as a unified code for 6G network.

The systems and methods described herein generalize and/or utilize LDPC codes for both data channels and control channels (e.g., for 6G networks). LDPC codes are capacity achieving and associated with moderately complex, and thus parallelizable, encoding and decoding schemes. For finite block lengths, the LDPC codes may be concatenated, which can result in more powerful codes without increasing complexity at decoders.

For example, the systems and methods introduce the concatenation of different quasi-cyclic LDPC codes, or QC-LDPC codes, where an inner code has a fixed high-rate code and an outer code is rate adaptable and/or flexible. A convolutional or block interleaver may be implemented between the concatenated codes, which may add a higher minimum distance and fewer low weight codewords. Thus, the concatenated QC-LDPC codes may be useful for finite block lengths, and the codes be uniformly applied across both data channels and control channels of a network (e.g., a 6G network), among other benefits.

Aspects of the present disclosure are described in the context of a wireless communications system.

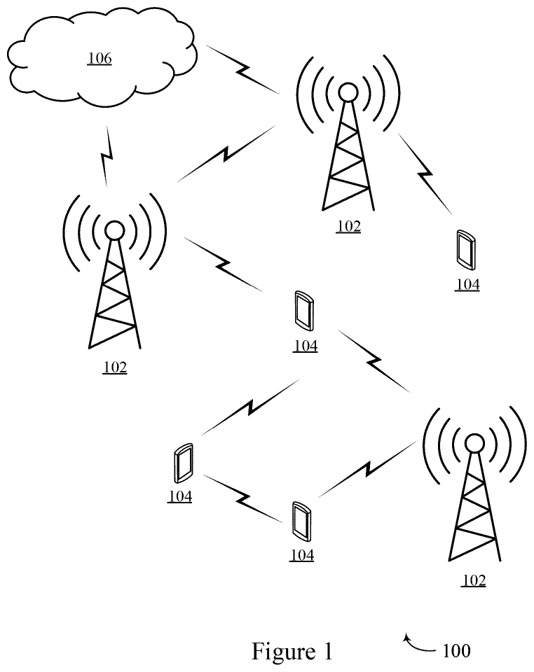

FIG. 1 illustrates an example of a wireless communications system 100 in accordance with aspects of the present disclosure. The wireless communications system 100 may include one or more NE 102, one or more UE 104, and a core network (CN) 106. The wireless communications system 100 may support various radio access technologies. In some implementations, the wireless communications system 100 may be a 4G network, such as an LTE network or an LTE-Advanced (LTE-A) network. In some other implementations, the wireless communications system 100 may be a NR network, such as a 5G network, a 5G-Advanced (5G-A) network, or a 5G ultrawideband (5G-UWB) network. In other implementations, the wireless communications system 100 may be a combination of a 4G network and a 5G network, or other suitable radio access technology including Institute of Electrical and Electronics Engineers (IEEE) 802.11 (Wi-Fi), IEEE 802.16 (WiMAX), IEEE 802.20. The wireless communications system 100 may support radio access technologies beyond 5G, for example, 6G. Additionally, the wireless communications system 100 may support technologies, such as time division multiple access (TDMA), frequency division multiple access (FDMA), or code division multiple access (CDMA), etc.

The one or more NE 102 may be dispersed throughout a geographic region to form the wireless communications system 100. One or more of the NE 102 described herein may be or include or may be referred to as a network node, a base station, a network element, a network function, a network entity, a radio access network (RAN), a NodeB, an eNodeB (eNB), a next-generation NodeB (gNB), or other suitable terminology. An NE 102 and a UE 104 may communicate via a communication link, which may be a wireless or wired connection. For example, an NE 102 and a UE 104 may perform wireless communication (e.g., receive signaling, transmit signaling) over a Uu interface.

An NE 102 may provide a geographic coverage area for which the NE 102 may support services for one or more UEs 104 within the geographic coverage area. For example, an NE 102 and a UE 104 may support wireless communication of signals related to services (e.g., voice, video, packet data, messaging, broadcast, etc.) according to one or multiple radio access technologies. In some implementations, an NE 102 may be moveable, for example, a satellite associated with a non-terrestrial network (NTN). In some implementations, different geographic coverage areas associated with the same or different radio access technologies may overlap, but the different geographic coverage areas may be associated with different NE 102.

The one or more UE 104 may be dispersed throughout a geographic region of the wireless communications system 100. A UE 104 may include or may be referred to as a remote unit, a mobile device, a wireless device, a remote device, a subscriber device, a transmitter device, a receiver device, or some other suitable terminology. In some implementations, the UE 104 may be referred to as a unit, a station, a terminal, or a client, among other examples. Additionally, or alternatively, the UE 104 may be referred to as an Internet-of-Things (IoT) device, an Internet-of-Everything (IoE) device, or machine-type communication (MTC) device, among other examples.

A UE 104 may be able to support wireless communication directly with other UEs 104 over a communication link. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link may be referred to as a sidelink. For example, a UE 104 may support wireless communication directly with another UE 104 over a PC5 interface.

An NE 102 may support communications with the CN 106, or with another NE 102, or both. For example, an NE 102 may interface with other NE 102 or the CN 106 through one or more backhaul links (e.g., S1, N2, N2, or network interface). In some implementations, the NE 102 may communicate with each other directly. In some other implementations, the NE 102 may communicate with each other or indirectly (e.g., via the CN 106. In some implementations, one or more NE 102 may include subcomponents, such as an access network entity, which may be an example of an access node controller (ANC). An ANC may communicate with the one or more UEs 104 through one or more other access network transmission entities, which may be referred to as a radio heads, smart radio heads, or transmission-reception points (TRPs).

The CN 106 may support user authentication, access authorization, tracking, connectivity, and other access, routing, or mobility functions. The CN 106 may be an evolved packet core (EPC), or a 5G core (5GC), which may include a control plane entity that manages access and mobility (e.g., a mobility management entity (MME), an access and mobility management functions (AMF)) and a user plane entity that routes packets or interconnects to external networks (e.g., a serving gateway (S-GW), a Packet Data Network (PDN) gateway (P-GW), or a user plane function (UPF)). In some implementations, the control plane entity may manage non-access stratum (NAS) functions, such as mobility, authentication, and bearer management (e.g., data bearers, signal bearers, etc.) for the one or more UEs 104 served by the one or more NE 102 associated with the CN 106.

The CN 106 may communicate with a packet data network over one or more backhaul links (e.g., via an S1, N2, N2, or another network interface). The packet data network may include an application server. In some implementations, one or more UEs 104 may communicate with the application server. A UE 104 may establish a session (e.g., a protocol data unit (PDU) session, or the like) with the CN 106 via an NE 102. The CN 106 may route traffic (e.g., control information, data, and the like) between the UE 104 and the application server using the established session (e.g., the established PDU session). The PDU session may be an example of a logical connection between the UE 104 and the CN 106 (e.g., one or more network functions of the CN 106).

In the wireless communications system 100, the NEs 102 and the UEs 104 may use resources of the wireless communications system 100 (e.g., time resources (e.g., symbols, slots, subframes, frames, or the like) or frequency resources (e.g., subcarriers, carriers)) to perform various operations (e.g., wireless communications). In some implementations, the NEs 102 and the UEs 104 may support different resource structures. For example, the NEs 102 and the UEs 104 may support different frame structures. In some implementations, such as in 4G, the NEs 102 and the UEs 104 may support a single frame structure. In some other implementations, such as in 5G and among other suitable radio access technologies, the NEs 102 and the UEs 104 may support various frame structures (i.e., multiple frame structures). The NEs 102 and the UEs 104 may support various frame structures based on one or more numerologies.

One or more numerologies may be supported in the wireless communications system 100, and a numerology may include a subcarrier spacing and a cyclic prefix. A first numerology (e.g., μ=0) may be associated with a first subcarrier spacing (e.g., 15 kHz) and a normal cyclic prefix. In some implementations, the first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=4) may be associated with a fifth subcarrier spacing (e.g., 240 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally, or alternatively, a time interval of a resource (e.g., a communication resource) may be organized according to slots. For example, a subframe may include a number (e.g., quantity) of slots. The number of slots in each subframe may also depend on the one or more numerologies supported in the wireless communications system 100. For instance, the first, second, third, fourth, and fifth numerologies (i.e., μ=0, μ=1, μ=2, μ=3, μ=4) associated with respective subcarrier spacings of 15 kHz, 30 kHz, 60 kHz, 120 kHz, and 240 kHz may utilize a single slot per subframe, two slots per subframe, four slots per subframe, eight slots per subframe, and 16 slots per subframe, respectively. Each slot may include a number (e.g., quantity) of symbols (e.g., OFDM symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communications system 100, an electromagnetic (EM) spectrum may be split, based on frequency or wavelength, into various classes, frequency bands, frequency channels, etc. By way of example, the wireless communications system 100 may support one or multiple operating frequency bands, such as frequency range designations FR1 (410 MHz-7.125 GHz), FR2 (24.25 GHz-52.6 GHz), FR3 (7.125 GHz-24.25 GHz), FR4 (52.6 GHz-114.25 GHz), FR4a or FR4-1 (52.6 GHz-71 GHz), and FR5 (114.25 GHz-300 GHz). In some implementations, the NEs 102 and the UEs 104 may perform wireless communications over one or more of the operating frequency bands. In some implementations, FR1 may be used by the NEs 102 and the UEs 104, among other equipment or devices for cellular communications traffic (e.g., control information, data). In some implementations, FR2 may be used by the NEs 102 and the UEs 104, among other equipment or devices for short-range, high data rate capabilities.

FR1 may be associated with one or multiple numerologies (e.g., at least three numerologies). For example, FR1 may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

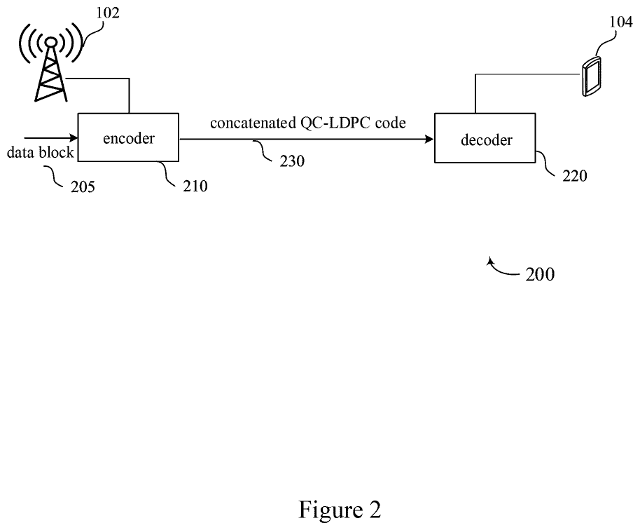

As described herein, the wireless communications system 100 may introduce mechanisms and/or procedures for the concatenation of two or more QC-LDPC codes in a serial or a parallel manner. The wireless communications system 100 may transmit the concatenated QC-LDPC codes between devices. FIG. 2 illustrates an example of signaling 200 a channel code between an NE and a UE in accordance with aspects of the present disclosure.

For example, an encoder 210 associated with a base station (e.g., the NE 102), or transmitter, receives a data block and generates a concatenated QC-LDPC code 230 for the data block 205, as described herein. The base station transmits the concatenated QC-LDPC code 230 to a UE (e.g., the UE 104), or receiver, which is associated with a decoder 220. The decoder 220 receives the concatenated QC-LDPC code 230 and decodes the code, as described herein. In some cases, the UE 104 may be a transmitter and associated with the encoder 210, operating to generate the concatenated QC-LDPC code 230, and the base station, or NE 102, may be the receiver and include the decoder 220, operating to decode the concatenated QC-LDPC code 230.

In some cases, the encoder 210 includes or inserts an interleaver and/or a puncturing block between internal encoders, such as the encoders of the inner codes and the outer codes of the concatenated codes. Thus, the concatenation of an QC-LDPC inner code, or [symbol] ᵢₙ {n₁, k₁, R₁}, and an QC-LDPC outer code, or [symbol] out {n₂, k₂, R₂}, is a QC-LDPC code, or [symbol] _{conct} {n₂, R₁R₂}, where nᵢ is a code length, kᵢ is a code dimension, and Rᵢ is a code rate iϵ{1,2}. The inner code may have a high code rate (e.g., close to 1) and the outer code may be selected as a rate-compatible code (e.g., a flexible or adaptable code rate). Alternatively, the outer code may have the high code rate (e.g., close to 1), while the inner code is rate compatible.

The decoder 220 may include a first iterative Tanner graph-based decoder for the inner code and a second iterative Tanner graph-based decoder for the outer code. In some cases, the decoder 220 also includes a de-interleaver that is added or inserted between any serial/parallel decoders. For example, the use of an interleaver (and de-interleaver) may enable a higher minimum distance and reduced number of low-weight codewords of the concatenated code, which can lead to a better performance at both waterfall and error floor regions.

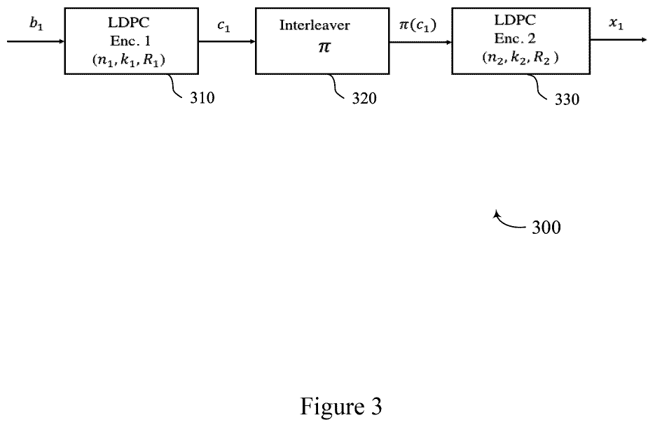

FIG. 3 illustrates an example serial concatenation 300 of interleaved concatenated channel codes in accordance with aspects of the present disclosure. In some cases, FIG. 3 illustrates components of a super encoder. Incoming data blocks b₁ are received by a first encoder 310 and encoded using an inner code. The output c₁ of the first encoder 310 is received by an interleaver 320, such as a block or convolutional interleaver, which scrambles the input c₁. A scrambled output is received by a second encoder 330 and encoded using an outer code.

For example, the inner code, [symbol] ₁ (n₁, k₁, R₁), is a QC-LDPC code with a sparse parity check matrix defined as H₁. The outer code, [symbol] ₂ (n₂, k₂, R₂), is a QC-LDPC code having a sparse parity check matrix H₂. For short block lengths, the parity check matrix of each component code (e.g., the inner code and/or the outer code) may be defined by two parameters, a (1) Base Graph 2 (e.g., as defined in TS38.212), and lifting sizes Z₁ and Z₂ that may depend on or be based on the corresponding code rates of each component code. Thus, a resulting transmitted codeword x₁ has a length n_{c}=n₂ and the code rate of the concatenated codes is R_{C}=R₁R₂.

In some cases, both the inner and outer codes are QC-LDPC codes, which are regular codes constructed using circulant permutations of base graphs, or alternatively, mother codes, such as the ones defined in TS 38.212. Further, the base graphs and the lifting sizes may be determined based on code rates R₁ and R₂ and code block lengths for the codes.

For example, the outer code may be selected as a rate-compatible (e.g., flexible and/or adaptable), and the inner code may be fixed at a high code rate (e.g., a rate close to 1). However, in other examples, the outer code may be fixed at the high code rate and the inner code may be the rate-compatible code. The combination of a high-rate code with a rate-compatible code, via an interleaver, may eliminate, via the high code rate, some or all unsuccessful decoding loops on the Tanner-graph of the rate-compatible code by adding a low number of parity checks that are randomly interleaved. Such a combination may improve or enhance the overall performance of the error correction and the coding gain with low processing overhead at an encoder and a decoder for a family of channel code, such as LDPC codes.

In some embodiments, an interleaver (e.g., the interleaver 320) introduces structured randomness to the transmitted codewords, which increases the minimum distance of the code and enables enhanced correction capabilities, and, thus, enhanced waterfall and error floor performance. For example, the interleaver may be a simple columns permutation, a block interleaver, such as a helical interleaver, an algebraic interleaver, such as a quadratic permutation polynomial (QPP) interleaver, a convolutional interleaver, a fitted interleaver, and so on. The selection and/or design of the interleaver may be based on a target performance and/or properties of a channel.

In some embodiments, the interleaver (e.g., the interleaver 320) may be based on a distance spectrum of the channel code and a correlation between the information input data and the soft output of each decoder corresponding to its parity bits. For example, the QC-LDPC code distance properties and spectrum may be determined using Gaussian elimination techniques or other similar techniques. The randomness is introduced by scrambling the first encoder output, which increases the minimum distance of the outer code. Thus, even when the code rate of the outer code is not high, the error correction performance of the code may be preserved.

In some embodiments, legacy bit-interleaving, as defined in TS38.212, of the LDPC codeword may be replaced by the interleaver, such as the interleaver 320 added between the concatenated inner and outer codes. Using the interleaver described herein may reduce the LDPC transmission chain and computational complexity, enabling latency gains with respect to encoding and decoding procedures, and thus providing an enhanced coding performance with high coding gains, among other benefits.

In some embodiments, two or more interleavers may be added between two or more concatenated LDPC codes, where an information bits sequence is encoded using two parallel outer codes separated by a first interleaver and that output is then input to a third inner code after going through a second interleaver. For example, the interleavers may perform the same set of permutations over the information bits, which enables a less complex hardware implementation and control signaling at the expense of a reduced performance. As another example, the interleavers may be separately or uniquely configured, based on distance properties of the inner or outer codes and/or the targeted performance.

In some embodiments, the encoder soft outputs may be interleaved over the parity check matrix, where the encoder uses the scrambled parity check matrix to encode the information bits. The interleaver may be a permutation of the columns of the parity check matrix. For example, the quasi-cyclic structure may be altered or modified, and the randomness generated by the interleaver is leveraged to achieve an enhanced performance and higher coding gain, among other benefits.

In some embodiments, data blocks with large packet sizes may be divided into sub-blocks of shorter block lengths before being encoded by the serially concatenated LDPC codes to avoid high interleaving delays. In such cases, a block undergoes a block segmentation procedure, and several packets of shorter sizes are generated and fed to the transmission chain (e.g., the first encoder 310).

A receiver (e.g., the decoder 220) may include two serially concatenated iterative decoders, separated by a de-interleaver, which decode a received codeword. For example, the soft outputs of the first decoder are provided to the de-interleaver and then decoded by a second iterative decoder. The second decoder may estimate the received signal. In some cases, as described herein, the decoder 220 may include a feedback loop, where the soft output of the second decoder is fed back to the first decoder, and after a number of iterations (e.g., to fine tune any extrinsic information), the second decoder outputs a hard decision on or for the codeword.

In some embodiments, the inner and outer encoding may be performed in a systematic manner. The decoding at the receiver may employ an equivalent Tanner graph [symbol] _{conc}, corresponding to a parity check matrix of the super encoder, where an iterative decoder is configured to exchange extrinsic information over an equivalent Tanner graph, using the parity check matrix corresponding to the concatenated codes.

For example, the component codes are [symbol] ₁ (n₁, k₁, R₁, H₁) and [symbol] ₂ (n₂, k₂, R₂, H₂), where H₁ and H₂ are the corresponding parity check matrices. In systematic form, a resulting codeword is C=[C₁, P₁, P₂], where C₁ is an information bits sequence, P₁ is a redundancy introduced by encoder 1, and P₂ is a redundancy introduced by encoder 2. P₂ includes checks on checks of the first encoder P₁, noted as P_{2(P}_{₁}₎. Since the same code is used as the inner and the outer code, the checks on checks may be safely punctured. The parity check matrix of the super encoder (e.g., the inner and outer codes) is as follows:

$${H}_{c o n c} = [ \begin{matrix}{H}_{1} & {L}_{{L}_{1}} \\ {H}_{{L}_{2}} & {H}_{2}\end{matrix} ]$$

where H_{L}_{₁} represents [symbol] ₁ checks- [symbol] ₂ variable associated matrix and H_{L}_{₂} represents [symbol] ₂ checks- [symbol] ₁ variable associated matrix. In the systematic form, and by zeroing additional redundancy caused by check on checks, H_{conc} may be written as follows:

$${H}_{c o n c} = [ \begin{matrix}{H}_{1} & {H}_{I} 0 \\ 0 & {H}_{2}\end{matrix} ]$$

where H₁ is an identity matrix. The resulting matrix is sparse and has a girth g_{conc} lower bounded by min {g₁, g₂, 8}, where g₁ and g₂ are Tanner graph girths of the outer and inner codes, respectively.

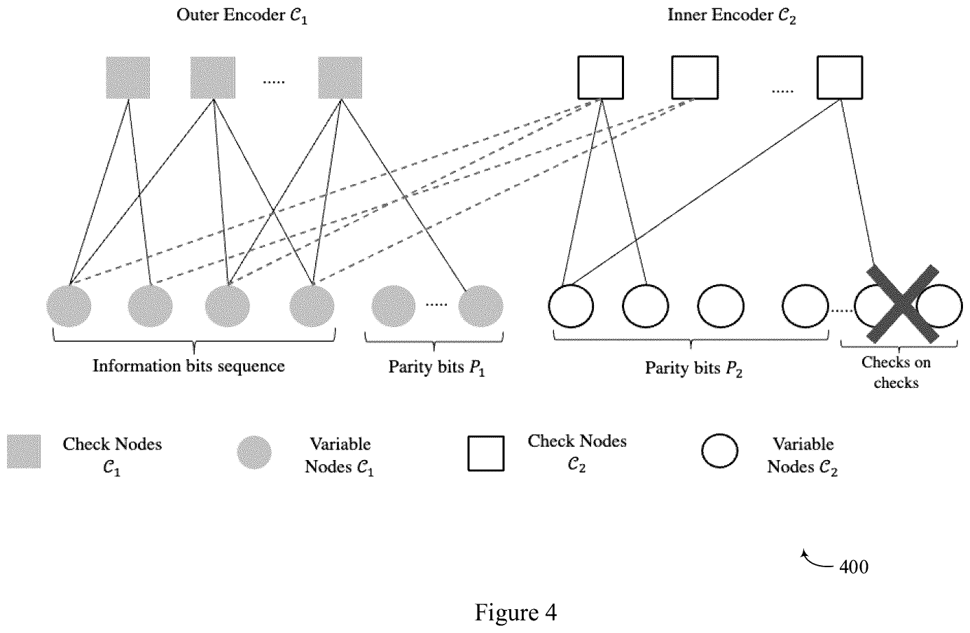

FIG. 4 illustrates an example Tanner Graph 400 for serially concatenated channel codes in accordance with aspects of the present disclosure. For example, the tanner graph 400 corresponds to the serially concatenated LDPC codes. The concatenated code may be decoded, as described herein, by the same iterative decoder exchanging extrinsic information over an equivalent Tanner graph and using the parity check matrix H_{conc}.

In some embodiments, the number or quantity of concatenated LDPC codes may be more than two, such as three QC-LDPC codes being used to encode the same data block at different rates. For example, two inner codes could have a high code rate (e.g., close to 1) and an outer code is rate-compatible (e.g., the code is selected using a coding scheme that can adapt to different channel conditions by selecting arbitrary coding rates applicable to the encoded codewords).

The use of additional (e.g., three or more) codes may further improve the BLER performance at a minimal expense of low-overhead additional computations (e.g., at the transmitter and the receiver). In some cases, the concatenation may be performed serially, where the output of the first encoder (e.g., the outer code) is fed to an interleaver, whose input is further fed to a second encoder (e.g., an inner code).

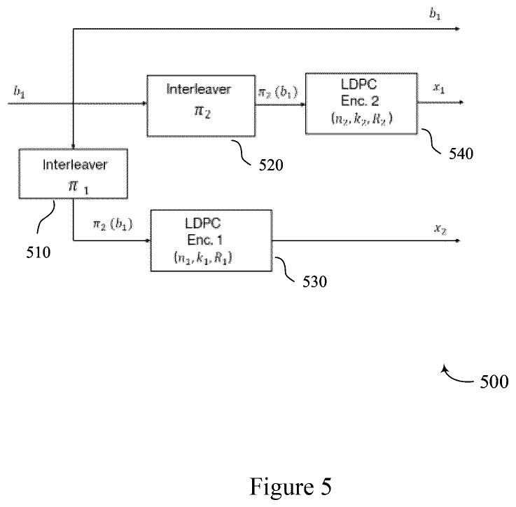

In some cases, the QC-LDPC codes may be concatenated in a parallel manner. FIG. 5 illustrates an example parallel concatenation 500 of interleaved channel codes in accordance with aspects of the present disclosure. Two outer codes are performed in parallel, and the input bits are fed, in parallel, into a first interleaver 510 and a second interleaver 520. The outputs of the interleavers 510, 520 are then fed, in parallel, into encoders 530, 540, which encode the different interleaved bits, as described herein.

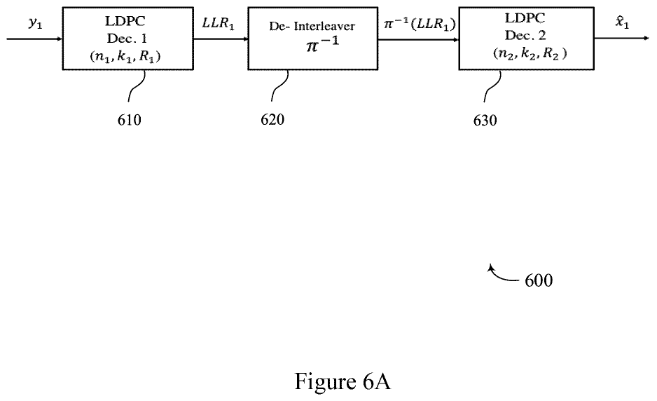

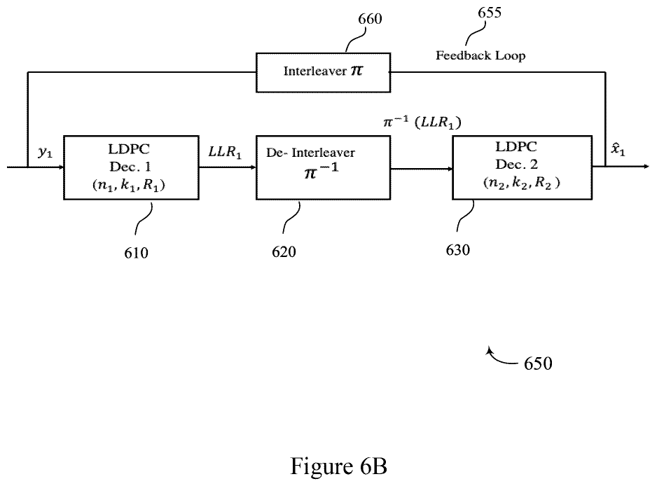

As described herein, the decoding of the codewords may be based on the concatenated codes. FIGS. 6A-6B illustrate example decoder structures in accordance with aspects of the present disclosure. In FIG. 6A, a decoder 600 includes a first decoder 610, which receives a codeword. The first decoder 610 may be a first iterative Tanner graph-based decoder, such as a belief propagation (BP) decoder, a min-sum algorithm (MSA) and so on.

The first decoder 610 may output extrinsic information (e.g., likelihood ratios, log-likelihood ratios, and so on). A de-interleaver 620 receives the output and reorders the soft input into a correct order of bits. A second decoder 630 receives the reordered soft input and decodes the soft output. The second decoder 630 may be an iterative Tanner graph-based decoder.

As described herein, a decoder, such as a decoder 650 of FIG. 6B, may include a feedback loop 655. The feedback loop 655 may include or insert an interleaver 660, which interleaves a soft output of the second decoder 640 is interleaved and inputs the interleaved input to the first decoder 610.

In some cases, the second decoder 630 may determine whether to utilize the feedback loop 655 based on reaching a number of maximum iterations or by achieving high likelihoods associated with the decoding. In some cases, the inputs of the decoders 610, 630 are connected to the output of each other, and the decoders 610, 630 are configured to pass soft information to each other during turbo-like decoding iterations.

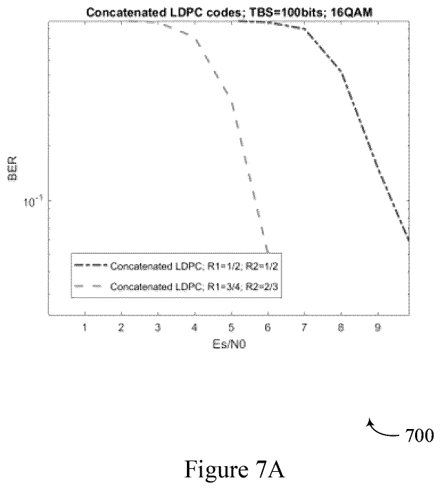

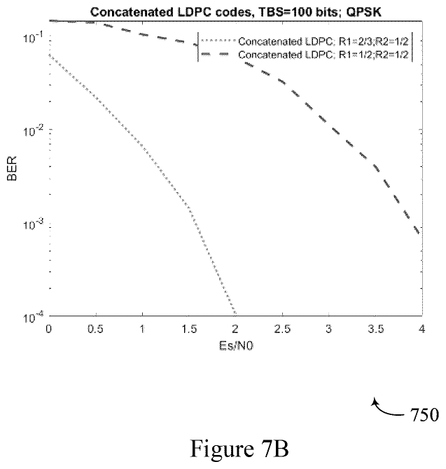

As described herein, the interleaved concatenated QC-LDPC codes may outperform polar codes for different transport block sizes and different code rates. Both quadrature phase shift keying (QPSK) and 16 quadrature amplitude modulation (QAM) constellations are considered in a low to moderate signal to noise (SNR) regime. In addition, concatenated LDPC codes may not exhibit an error floor at low BERs. FIGS. 7A-7B illustrate example graphs depicting the performance of concatenated QC-LDPC codes in accordance with aspects of the present disclosure.

A simulation of the performance of the codes included the following setup, as illustrated in Table 1:

TABLE 1

| | Concatenated | LDPC |
|---|---|---|
| | LDPC codes | Codes |
| Transport block | 100 bits | 100 bits |
| size/CB size | | |
| Decoding Algorithm | Iterative | Belief |
| | decoding (Belief | propagation |
| | propagation) | (BP) |
| Modulation scheme | QPSK | QPSK |
| | 16QAM | |
| Interleaving | Interleaving | NA |
| | Block | |

As depicted in graph 700 of FIG. 7A (with 16QAM modulation and TB=100 bits) and in graph 750 of FIG. 7B (with QPSK modulation and TB=100 bits) the concatenated QC-LDPC codes exhibit a good BER performance both at the waterfall and error floor regions for different code rates, code block sizes, and modulation formats. Thus, the interleaved concatenated LDPC codes may be utilized for short or finite block length regimes (e.g., for control channels, such as physical downlink control channel (PDCCH) transmissions), while exhibiting a suitable or favorable bit error rate performance.

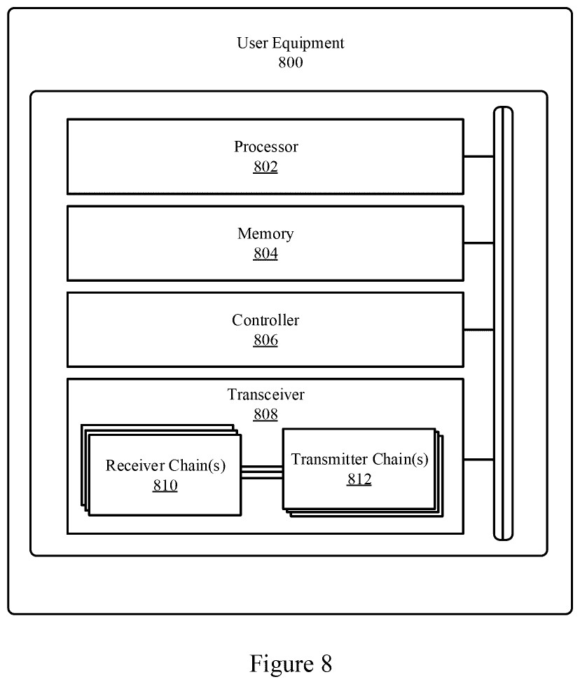

FIG. 8 illustrates an example of a UE 800 in accordance with aspects of the present disclosure. The UE 800 may include a processor 802, a memory 804, a controller 806, and a transceiver 808. The processor 802, the memory 804, the controller 806, or the transceiver 808, or various combinations thereof or various components thereof may be examples of means for performing various aspects of the present disclosure as described herein. These components may be coupled (e.g., operatively, communicatively, functionally, electronically, electrically) via one or more interfaces.

The processor 802, the memory 804, the controller 806, or the transceiver 808, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 802 may include an intelligent hardware device (e.g., a general-purpose processor, a DSP, a CPU, an ASIC, an FPGA, or any combination thereof). In some implementations, the processor 802 may be configured to operate the memory 804. In some other implementations, the memory 804 may be integrated into the processor 802. The processor 802 may be configured to execute computer-readable instructions stored in the memory 804 to cause the UE 800 to perform various functions of the present disclosure.

The memory 804 may include volatile or non-volatile memory. The memory 804 may store computer-readable, computer-executable code including instructions when executed by the processor 802 cause the UE 800 to perform various functions described herein. The code may be stored in a non-transitory computer-readable medium such the memory 804 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 802 and the memory 804 coupled with the processor 802 may be configured to cause the UE 800 to perform one or more of the functions described herein (e.g., executing, by the processor 802, instructions stored in the memory 804). For example, the processor 802 may support wireless communication at the UE 800 in accordance with examples as disclosed herein. The UE 800 may be configured to support a means for receiving a data block and generating a concatenated QC-LDPC code for the data block, by performing a first QC-LDPC encoding of the data block at a first code rate to generate an encoded data block, interleaving QC-LDPC codeword elements of the encoded data block to generate an interleaved encoded data block, and performing a second QC-LDPC encoding of the encoded data block at a second code rate.

As another example, the UE 800 may be configured to support a means for receiving a QC-LDPC code, decoding an outer code of the concatenated QC-LDPC code via a first iterative decoder to generate decoded bits, de-interleaving QC-LDPC bit elements of the outer code to generate de-interleaved decoded bits, and decoding an inner code of the de-interleaved decoded bits via a second iterative decoder.

The controller 806 may manage input and output signals for the UE 800. The controller 806 may also manage peripherals not integrated into the UE 800. In some implementations, the controller 806 may utilize an operating system such as iOS®, ANDROID®, WINDOWS®, or other operating systems. In some implementations, the controller 806 may be implemented as part of the processor 802.

In some implementations, the UE 800 may include at least one transceiver 808. In some other implementations, the UE 800 may have more than one transceiver 808. The transceiver 808 may represent a wireless transceiver. The transceiver 808 may include one or more receiver chains 810, one or more transmitter chains 812, or a combination thereof.

A receiver chain 810 may be configured to receive signals (e.g., control information, data, packets) over a wireless medium. For example, the receiver chain 810 may include one or more antennas for receive the signal over the air or wireless medium. The receiver chain 810 may include at least one amplifier (e.g., a low-noise amplifier (LNA)) configured to amplify the received signal. The receiver chain 810 may include at least one demodulator configured to demodulate the receive signal and obtain the transmitted data by reversing the modulation technique applied during transmission of the signal. The receiver chain 810 may include at least one decoder for decoding the processing the demodulated signal to receive the transmitted data.

A transmitter chain 812 may be configured to generate and transmit signals (e.g., control information, data, packets). The transmitter chain 812 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 812 may also include at least one power amplifier configured to amplify the modulated signal to an appropriate power level suitable for transmission over the wireless medium. The transmitter chain 812 may also include one or more antennas for transmitting the amplified signal into the air or wireless medium.

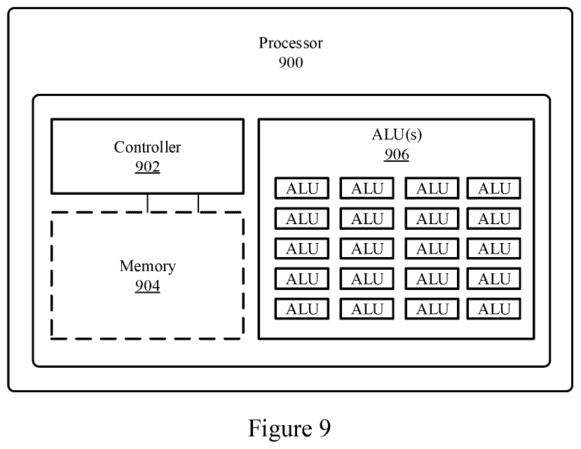

FIG. 9 illustrates an example of a processor 900 in accordance with aspects of the present disclosure. The processor 900 may be an example of a processor configured to perform various operations in accordance with examples as described herein. The processor 900 may include a controller 902 configured to perform various operations in accordance with examples as described herein. The processor 900 may optionally include at least one memory 904, which may be, for example, an L1/L2/L3 cache. Additionally, or alternatively, the processor 900 may optionally include one or more arithmetic-logic units (ALUs) 906. One or more of these components may be in electronic communication or otherwise coupled (e.g., operatively, communicatively, functionally, electronically, electrically) via one or more interfaces (e.g., buses).

The processor 900 may be a processor chipset and include a protocol stack (e.g., a software stack) executed by the processor chipset to perform various operations (e.g., receiving, obtaining, retrieving, transmitting, outputting, forwarding, storing, determining, identifying, accessing, writing, reading) in accordance with examples as described herein. The processor chipset may include one or more cores, one or more caches (e.g., memory local to or included in the processor chipset (e.g., the processor 900) or other memory (e.g., random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others).

The controller 902 may be configured to manage and coordinate various operations (e.g., signaling, receiving, obtaining, retrieving, transmitting, outputting, forwarding, storing, determining, identifying, accessing, writing, reading) of the processor 900 to cause the processor 900 to support various operations in accordance with examples as described herein. For example, the controller 902 may operate as a control unit of the processor 900, generating control signals that manage the operation of various components of the processor 900. These control signals include enabling or disabling functional units, selecting data paths, initiating memory access, and coordinating timing of operations.

The controller 902 may be configured to fetch (e.g., obtain, retrieve, receive) instructions from the memory 904 and determine subsequent instruction(s) to be executed to cause the processor 900 to support various operations in accordance with examples as described herein. The controller 902 may be configured to track memory address of instructions associated with the memory 904. The controller 902 may be configured to decode instructions to determine the operation to be performed and the operands involved. For example, the controller 902 may be configured to interpret the instruction and determine control signals to be output to other components of the processor 900 to cause the processor 900 to support various operations in accordance with examples as described herein. Additionally, or alternatively, the controller 902 may be configured to manage flow of data within the processor 900. The controller 902 may be configured to control transfer of data between registers, arithmetic logic units (ALUs), and other functional units of the processor 900.

The memory 904 may include one or more caches (e.g., memory local to or included in the processor 900 or other memory, such RAM, ROM, DRAM, SDRAM, SRAM, MRAM, flash memory, etc. In some implementations, the memory 904 may reside within or on a processor chipset (e.g., local to the processor 900). In some other implementations, the memory 904 may reside external to the processor chipset (e.g., remote to the processor 900).

The memory 904 may store computer-readable, computer-executable code including instructions that, when executed by the processor 900, cause the processor 900 to perform various functions described herein. The code may be stored in a non-transitory computer-readable medium such as system memory or another type of memory. The controller 902 and/or the processor 900 may be configured to execute computer-readable instructions stored in the memory 904 to cause the processor 900 to perform various functions. For example, the processor 900 and/or the controller 902 may be coupled with or to the memory 904, the processor 900, the controller 902, and the memory 904 may be configured to perform various functions described herein. In some examples, the processor 900 may include multiple processors and the memory 904 may include multiple memories. One or more of the multiple processors may be coupled with one or more of the multiple memories, which may, individually or collectively, be configured to perform various functions herein.

The one or more ALUs 906 may be configured to support various operations in accordance with examples as described herein. In some implementations, the one or more ALUs 906 may reside within or on a processor chipset (e.g., the processor 900). In some other implementations, the one or more ALUs 906 may reside external to the processor chipset (e.g., the processor 900). One or more ALUs 906 may perform one or more computations such as addition, subtraction, multiplication, and division on data. For example, one or more ALUs 906 may receive input operands and an operation code, which determines an operation to be executed. One or more ALUs 906 be configured with a variety of logical and arithmetic circuits, including adders, subtractors, shifters, and logic gates, to process and manipulate the data according to the operation. Additionally, or alternatively, the one or more ALUs 906 may support logical operations such as AND, OR, exclusive-OR (XOR), not-OR (NOR), and not-AND (NAND), enabling the one or more ALUs 906 to handle conditional operations, comparisons, and bitwise operations.

The processor 900 may support wireless communication in accordance with examples as disclosed herein. The processor 900 may be configured to support a means for receiving a data block and generating a concatenated QC-LDPC code for the data block, by performing a first QC-LDPC encoding of the data block at a first code rate to generate an encoded data block, interleaving QC-LDPC codeword elements of the encoded data block to generate an interleaved encoded data block, and performing a second QC-LDPC encoding of the encoded data block at a second code rate.

As another example, the processor 900 may be configured to support a means for receiving a QC-LDPC code, decoding an outer code of the concatenated QC-LDPC code via a first iterative decoder to generate decoded bits, de-interleaving QC-LDPC bit elements of the outer code to generate de-interleaved decoded bits, and decoding an inner code of the de-interleaved decoded bits via a second iterative decoder.

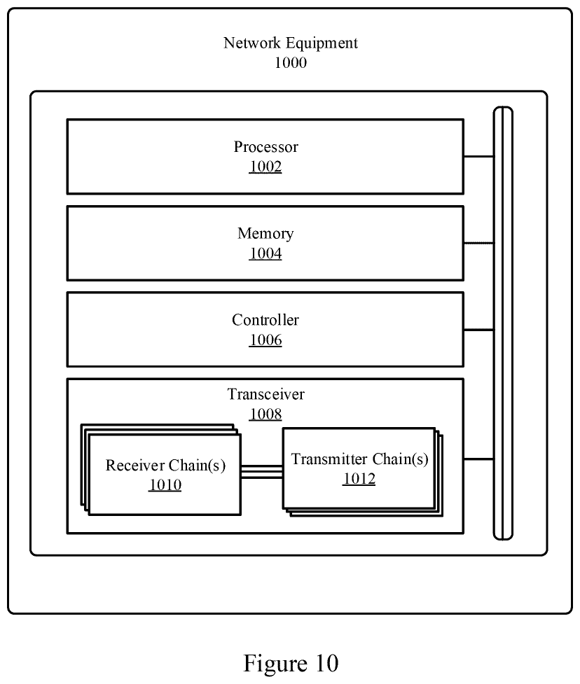

FIG. 10 illustrates an example of a NE 1000 in accordance with aspects of the present disclosure. The NE 1000 may include a processor 1002, a memory 1004, a controller 1006, and a transceiver 1008. The processor 1002, the memory 1004, the controller 1006, or the transceiver 1008, or various combinations thereof or various components thereof may be examples of means for performing various aspects of the present disclosure as described herein. These components may be coupled (e.g., operatively, communicatively, functionally, electronically, electrically) via one or more interfaces.

The processor 1002, the memory 1004, the controller 1006, or the transceiver 1008, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 1002 may include an intelligent hardware device (e.g., a general-purpose processor, a DSP, a CPU, an ASIC, an FPGA, or any combination thereof). In some implementations, the processor 1002 may be configured to operate the memory 1004. In some other implementations, the memory 1004 may be integrated into the processor 1002. The processor 1002 may be configured to execute computer-readable instructions stored in the memory 1004 to cause the NE 1000 to perform various functions of the present disclosure.

The memory 1004 may include volatile or non-volatile memory. The memory 1004 may store computer-readable, computer-executable code including instructions when executed by the processor 1002 cause the NE 1000 to perform various functions described herein. The code may be stored in a non-transitory computer-readable medium such the memory 1004 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 1002 and the memory 1004 coupled with the processor 1002 may be configured to cause the NE 1000 to perform one or more of the functions described herein (e.g., executing, by the processor 1002, instructions stored in the memory 1004). For example, the processor 1002 may support wireless communication at the NE 1000 in accordance with examples as disclosed herein. The NE 1000 may be configured to support a means for receiving a data block and generating a concatenated QC-LDPC code for the data block, by performing a first QC-LDPC encoding of the data block at a first code rate to generate an encoded data block, interleaving QC-LDPC codeword elements of the encoded data block to generate an interleaved encoded data block, and performing a second QC-LDPC encoding of the encoded data block at a second code rate.

As another example, the NE 1000 may be configured to support a means for receiving a QC-LDPC code, decoding an outer code of the concatenated QC-LDPC code via a first iterative decoder to generate decoded bits, de-interleaving QC-LDPC bit elements of the outer code to generate de-interleaved decoded bits, and decoding an inner code of the de-interleaved decoded bits via a second iterative decoder.

The controller 1006 may manage input and output signals for the NE 1000. The controller 1006 may also manage peripherals not integrated into the NE 1000. In some implementations, the controller 1006 may utilize an operating system such as iOS®, ANDROID®, WINDOWS®, or other operating systems. In some implementations, the controller 1006 may be implemented as part of the processor 1002.

In some implementations, the NE 1000 may include at least one transceiver 1008. In some other implementations, the NE 1000 may have more than one transceiver 1008. The transceiver 1008 may represent a wireless transceiver. The transceiver 1008 may include one or more receiver chains 1010, one or more transmitter chains 1012, or a combination thereof.

A receiver chain 1010 may be configured to receive signals (e.g., control information, data, packets) over a wireless medium. For example, the receiver chain 1010 may include one or more antennas for receive the signal over the air or wireless medium. The receiver chain 1010 may include at least one amplifier (e.g., a low-noise amplifier (LNA)) configured to amplify the received signal. The receiver chain 1010 may include at least one demodulator configured to demodulate the receive signal and obtain the transmitted data by reversing the modulation technique applied during transmission of the signal. The receiver chain 1010 may include at least one decoder for decoding the processing the demodulated signal to receive the transmitted data.

A transmitter chain 1012 may be configured to generate and transmit signals (e.g., control information, data, packets). The transmitter chain 1012 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 1012 may also include at least one power amplifier configured to amplify the modulated signal to an appropriate power level suitable for transmission over the wireless medium. The transmitter chain 1012 may also include one or more antennas for transmitting the amplified signal into the air or wireless medium.

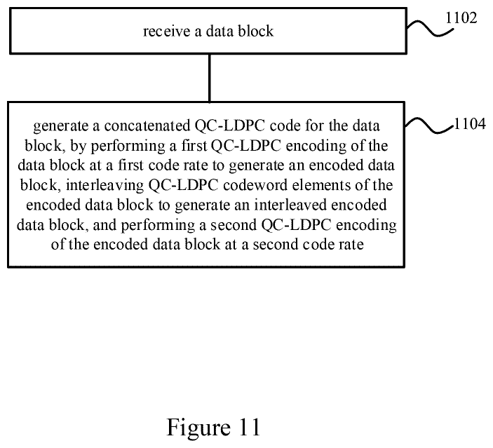

FIG. 11 illustrates a flowchart of a method in accordance with aspects of the present disclosure. The operations of the method may be implemented by a UE or NE as described herein. In some implementations, the UE or NE may execute a set of instructions to control the function elements of the UE or NE to perform the described functions.

At 1102, the method may include receiving a data block. The operations of 1102 may be performed in accordance with examples as described herein. In some implementations, aspects of the operations of 1102 may be performed by a UE or an NE as described with reference to FIG. 8 or FIG. 10.

At 1104, the method may include generating a concatenated QC-LDPC code for the data block, by performing a first QC-LDPC encoding of the data block at a first code rate to generate an encoded data block, interleaving QC-LDPC codeword elements of the encoded data block to generate an interleaved encoded data block and performing a second QC-LDPC encoding of the encoded data block at a second code rate. The operations of 1104 may be performed in accordance with examples as described herein. In some implementations, aspects of the operations of 1104 may be performed by a UE or an NE as described with reference to FIG. 8 or FIG. 10.

It should be noted that the method described herein describes a possible implementation, and that the operations and the steps may be rearranged or otherwise modified and that other implementations are possible.

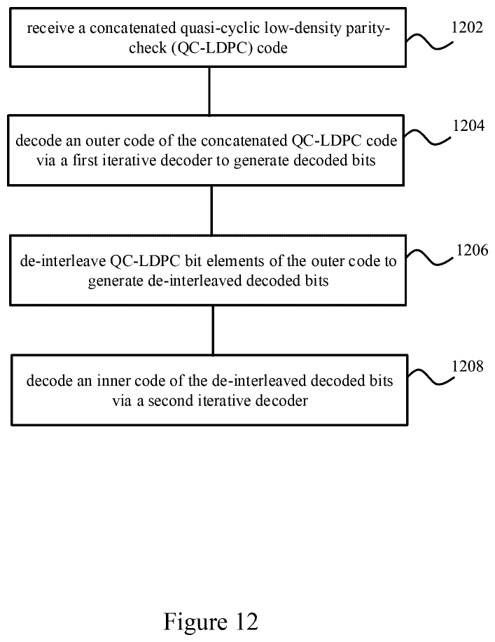

FIG. 12 illustrates a flowchart of a method in accordance with aspects of the present disclosure. The operations of the method may be implemented by a UE, acting as a reader device, as described herein. In some implementations, the UE may execute a set of instructions to control the function elements of the UE to perform the described functions.

At 1202, the method may include receiving a QC-LDPC code. The operations of 1202 may be performed in accordance with examples as described herein. In some implementations, aspects of the operations of 1202 may be performed by a UE or an NE as described with reference to FIG. 8 or FIG. 10.

At 1204, the method may include decoding an outer code of the concatenated QC-LDPC code via a first iterative decoder to generate decoded bits. The operations of 1204 may be performed in accordance with examples as described herein. In some implementations, aspects of the operations of 1204 may be performed by a UE or an NE as described with reference to FIG. 8 or FIG. 10.

At 1206, the method may include de-interleaving QC-LDPC bit elements of the outer code to generate de-interleaved decoded bits. The operations of 1206 may be performed in accordance with examples as described herein. In some implementations, aspects of the operations of 1206 may be performed by a UE or an NE as described with reference to FIG. 8 or FIG. 10.

At 1208, the method may include decoding an inner code of the de-interleaved decoded bits via a second iterative decoder. The operations of 1208 may be performed in accordance with examples as described herein. In some implementations, aspects of the operations of 1208 may be performed by a UE or an NE as described with reference to FIG. 8 or FIG. 10.

It should be noted that the method described herein describes a possible implementation, and that the operations and the steps may be rearranged or otherwise modified and that other implementations are possible.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A network entity for wireless communication, comprising:
at least one memory; and
at least one processor coupled with the at least one memory and configured to cause the network entity to:
receive a data block; and
generate a concatenated quasi-cyclic low-density parity-check (QC-LDPC) code for the data block, by:
performing a first QC-LDPC encoding of the data block at a first code rate to generate an encoded data block;
interleaving QC-LDPC codeword elements of the encoded data block to generate an interleaved encoded data block; and
performing a second QC-LDPC encoding of the interleaved encoded data block at a second code rate.

2. The network entity of claim 1, wherein the first code rate is close to 1 and the second code is flexible.

3. The network entity of claim 1, wherein the second code rate is close to 1 and the first code is flexible.

4. The network entity of claim 1, wherein the at least one processor is further configured to cause the network entity to:
puncture an output of an encoder that performed the first QC-LDPC encoding to reduce low weight codeword elements within the first QC-LDPC encoding.

5. The network entity of claim 1, wherein the first QC-LDPC encoding and the second QC-LDPC encoding are concatenated in a serial manner.

6. The network entity of claim 1, wherein the first QC-LDPC encoding and the second QC-LDPC encoding are concatenated in a parallel manner.

7. The network entity of claim 1, wherein the at least one processor is configured to cause the network entity to interleave QC-LDPC codeword elements of the first QC-LDPC encoding using a block interleaver, a convolutional interleaver, or a fitted interleaver.

8. The network entity of claim 1, wherein the at least one processor is further configured to cause the network entity to:
transmit the concatenated QC-LDPC code to a receiving entity.

9. A user equipment (UE) for wireless communication, comprising:
at least one memory; and
at least one processor coupled with the at least one memory and configured to cause the UE to:
receive a concatenated quasi-cyclic low-density parity-check (QC-LDPC) code;
decode an outer code of the concatenated QC-LDPC code via a first iterative decoder to generate decoded bits;
de-interleave decoded QC-LDPC bit elements of the outer code to generate de-interleaved decoded bits; and
decode an inner code of the de-interleaved decoded bits via a second iterative decoder.

10. The UE of claim 9, wherein the at least one processor is configured to cause the UE to:
de-interleave soft outputs of the first iterative decoder;
input the de-interleaved soft outputs to the second iterative decoder;
interleave soft outputs of the second iterative decoder; and
input the interleaved soft outputs of the second iterative decoder to the first iterative decoder.

11. The UE of claim 9, wherein the first iterative decoder or the second iterative decoder is a belief propagation decoder.

12. The UE of claim 9, wherein the first iterative decoder or the second iterative decoder is a min-sum algorithm decoder.

13. The UE of claim 9, wherein the first iterative decoder or the second iterative decoder is a decoder that applies a message passing algorithm.

14. The UE of claim 9, wherein the at least one processor is further configured to cause the UE to decode the inner code and the outer code of the concatenated QC-LDPC code via a joint iterative decoder,
wherein the joint iterative decoder exchanges extrinsic information over a Tanner graph associated with a parity check matrix of the concatenated codes; and
wherein the concatenated QC-LDPC code is in systematic form.

15. The UE of claim 14, wherein the Tanner graph associated with the parity check matrix of the concatenated QC-LDPC code includes a first set of variable nodes representing information bits, a second set of variable nodes representing parity bits of a first encoder, a third set of variable nodes representing parity bits of a second encoder, and a fourth set of variable nodes representing a check on checks.

16. The UE of claim 15, wherein the set of variable nodes representing the check on checks is punctured.

17. A method performed by a network entity, the method comprising:
receiving a data block; and
generating a concatenated quasi-cyclic low-density parity-check (QC-LDPC) code for the data block, by:
performing a first QC-LDPC encoding of the data block at a first code rate to generate an encoded data block;
interleaving QC-LDPC codeword elements of the encoded data block to generate an interleaved encoded data block; and
performing a second QC-LDPC encoding of the interleaved encoded data block at a second code rate.

18. The method of claim 17, further comprising:
puncturing an output of the first QC-LDPC encoding to reduce low weight codeword elements within the first QC-LDPC encoding.

19. A processor for wireless communication, comprising:
at least one controller coupled with at least one memory and configured to cause the processor to:
receive a concatenated quasi-cyclic low-density parity-check (QC-LDPC) code;
decode an outer code of the concatenated QC-LDPC code via a first iterative decoder to generate decoded bits;
de-interleave decoded QC-LDPC bit elements of the outer code to generate de-interleaved decoded bits; and
decode an inner code of the de-interleaved decoded bits via a second iterative decoder.

20. The processor of claim 19, wherein the at least one controller is configured to cause the processor to:
de-interleave soft outputs of the first iterative decoder;
input the de-interleaved soft outputs to the second iterative decoder;
interleave soft outputs of the second iterative decoder; and
input the interleaved soft outputs of the second iterative decoder to the first iterative decoder.
